(19) United States
(12) Patent Application Publication
(10) Pub. No.: US 2026/0173767 A1
(43) Pub. Date: Jun. 18, 2026

(54) SEMICONDUCTOR DEVICE AND METHOD FOR FABRICATING THE SAME

(71) Applicant: SK hynix Inc., Gyeonggi-do (KR)

(72) Inventors: Ku Youl JUNG, Gyeonggi-do (KR); Jung Hyeok KWAK, Gyeonggi-do (KR); Tae Yup KIM, Gyeonggi-do (KR); Jin Won JUNG, Gyeonggi-do (KR); Young Ki CHAI, Gyeonggi-do (KR)

(21) Appl. No.: 19/258,893

(22) Filed: Jul. 3, 2025

(30) Foreign Application Priority Data
Dec. 18, 2024 (KR) 10-2024-0189518

(51) Int. Cl. H10N 50/85; H10B 61/00; H10N 50/01; H10N 50/10

(52) U.S. Cl. CPC H10N 50/85; H10B 61/10; H10N 50/01; H10N 50/10

(57) ABSTRACT

Disclosed are a semiconductor device, and a method for fabricating the semiconductor device. A semiconductor device includes an interlayer insulating film disposed on a substrate and having a recess exposing a portion of the substrate; a bottom electrode contact embedding at least a portion of the recesses; a magnetic tunnel junction (MTJ) layer disposed on the interlayer insulating film and the bottom electrode contact; and a shift canceling layer having a magnetization direction antiparallel to the fixed layer, wherein the shift canceling layer may comprise a Co alloy, Fe alloy, Ni alloy or Mn alloy comprising at least one selected from the group consisting of Al, Ga, B, Ir, Zr, Hf and rare earth metals, or a ternary or quaternary Co alloy, Fe alloy or Ni alloy comprising one of Pt or Pd and at least one selected from the group consisting of Cr, Al, Tb, Si and B.

### CROSS-REFERENCE TO RELATED APPLICATIONS

The present application claims priority under 35 U.S.C 119(a) to Korean Patent Application No. 10-2024-0189518, filed on Dec. 18, 2024, which is incorporated herein by reference in its entirety.

### BACKGROUND

### 1. Field

Various embodiments of the present disclosure relate to semiconductor technology, and more particularly, to a semiconductor device including magnetic tunnel junction structures, and a method for fabricating the semiconductor device.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices. Researchers and the industry are studying to develop such semiconductor devices. The semiconductor devices are capable of storing data by taking advantage of the characteristics of switching between different resistance states according to the applied voltage or current, for example, a Resistive Random Access Memory (RRAM), a Phase-change Random Access Memory (PRAM), a Ferroelectric Random Access Memory (FRAM), a Magnetic Random Access Memory (MRAM), an e-fuse and the like.

### SUMMARY

Embodiments of the present disclosure are directed to a semiconductor device and a method of fabrication thereof that can provide stable exchange coupling at high temperatures while achieving high exchange bias field (Hex) and magnetoresistance (MR) by forming a synthetic antiferromagnetic (SAF) structure under a magnetic tunnel junction (MTJ) structure and a shift canceling layer (SCL) using a specific alloy, thereby preventing degradation of SAF properties that may occur during high temperature heat treatment.

In accordance with an embodiment of the present disclosure, a semiconductor device includes a substrate; an interlayer insulating film disposed on the substrate, and having a recess exposing a portion of the substrate; a bottom electrode contact (BEC) embedding at least a portion of the recess; a magnetic tunnel junction (MTJ) layer comprising a fixed layer disposed on the interlayer insulating film and the bottom electrode contact, and having a fixed magnetization direction, a free layer having a changeable magnetization direction, and a tunnel barrier layer interposed between the free layer and the fixed layer; and a shift canceling layer having a magnetization direction antiparallel to the fixed layer, wherein the shift canceling layer comprises a magnetic alloy selected from the group consisting of: (i) a cobalt (Co)-based alloy or an iron (Fe)-based alloy comprising at least one element selected from the group consisting of aluminum (Al), gallium (Ga), boron (B), iridium (Ir), zirconium (Zr), hafnium (Hf), and rare earth metals; (ii) nickel (Ni)-based alloy or manganese (Mn)-based alloy comprising at least one element selected from the group consisting of aluminum (Al), gallium (Ga), boron (B), iridium (Ir), zirconium (Zr), hafnium (Hf), and rare earth metals; and (iii) a ternary or quaternary alloy comprising Co, Fe, or Ni, and further comprising one of platinum (Pt) or lead (Pd), and at least one element selected from the group consisting of chromium (Cr), aluminum (Al), terbium (Tb), silicon (Si), and boron (B).

In accordance with another embodiment of the present disclosure, a method for fabricating a semiconductor device includes forming an interlayer insulating film on a substrate; selectively etching the interlayer insulating film to form a recess exposing a portion of the substrate; forming a bottom electrode contact embedding at least a portion of the recess; and forming a shift canceling layer and a variable resistance element on the bottom electrode contact, wherein the shift canceling layer comprises a magnetic alloy selected from the group consisting of: (i) a cobalt (Co)-based alloy or an iron (Fe)-based alloy comprising at least one element selected from the group consisting of aluminum (Al), gallium (Ga), boron (B), iridium (Ir), zirconium (Zr), hafnium (Hf), and rare earth metals; (ii) nickel (Ni)-based alloy or manganese (Mn)-based alloy comprising at least one element selected from the group consisting of aluminum (Al), gallium (Ga), boron (B), iridium (Ir), zirconium (Zr), hafnium (Hf), and rare earth metals; and (iii) a ternary or quaternary alloy comprising Co, Fe, or Ni, and further comprising one of platinum (Pt) or lead (Pd), and at least one element selected from the group consisting of chromium (Cr), aluminum (Al), terbium (Tb), silicon (Si), and boron (B).

### BRIEF DESCRIPTION OF THE DRAWINGS

FIGS. 1A to 1C are perspective and cross-sectional views illustrating a semiconductor device according to an embodiment of the present disclosure.

FIGS. 2A to 2G are cross-sectional views to illustrate a semiconductor device and a manufacturing method thereof, according to an embodiment of the present disclosure.

FIGS. 3A to 3H are cross-sectional views to illustrate a semiconductor device and a method of manufacturing the same, according to another embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, various embodiments of the present disclosure will be described in detail with reference to the attached drawings.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

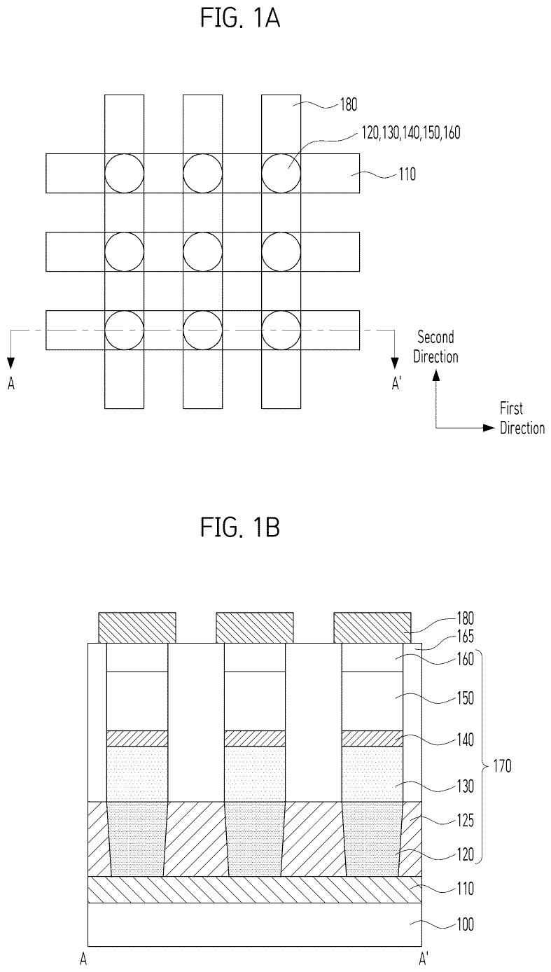

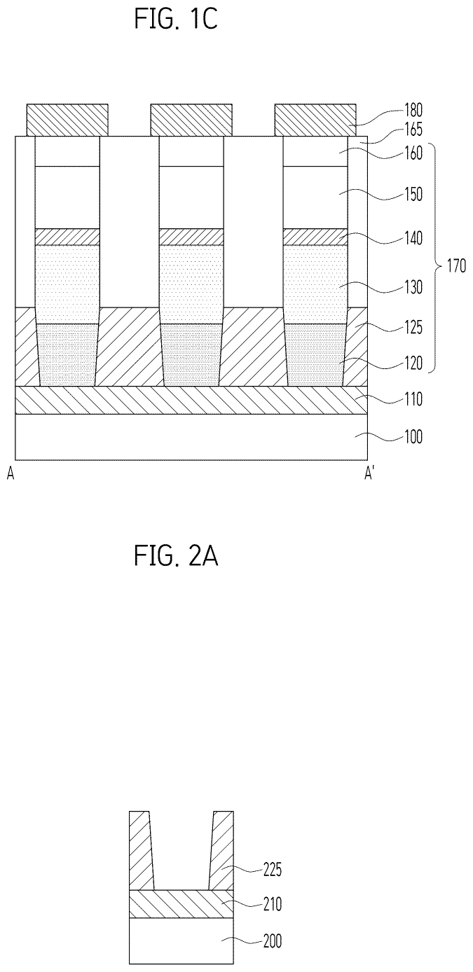

FIGS. 1A to 1C are perspective and cross-sectional views illustrating a semiconductor device according to an embodiment of the present disclosure. FIG. 1A illustrates a perspective view, and FIGS. 1B and 1C illustrate cross-sectional views along lines A-A′ in FIG. 1A.

Referring to FIGS. 1A to 1C, a semiconductor device according to an embodiment may have a crosspoint structure. The crosspoint structure may include a first wiring 110 formed on the substrate 100 and extending in a first direction, a second wiring 180 located on the first wiring 110 and extending in a second direction intersecting the first direction, and a memory cell 170 disposed at a respective intersection between the first wiring 110 and the second wiring 180.

The substrate 100 may include a semiconductor material, such as silicon or the like. Within the substrate 100, any desired predetermined substructure may be formed. For example, the substructure may include a drive circuit electrically connected to control the first wiring 110 and/or the second wiring 180, which are formed on the substrate 100.

The first wiring 110 and the second wiring 180 may be in communication with the memory cell 170 to deliver voltage or current to the memory cell 170 to drive the memory cell 170. One of the first wiring 110 and the second wiring 180 may function as a wordline and the other may function as a bitline. Each of the first wiring 110 and the second wiring 180 may have a single-membrane structure or a multi-membrane structure comprising a conductive material. Examples of conductive materials may include, but are not limited to metals, metal nitrides, conductive carbon materials, or combinations thereof. For example, the first wiring 110 and the second wiring 180 may comprise tungsten (W), titanium (Ti), tantalum (Ta), platinum (Pt), aluminum (Al), copper (Cu), zinc (Zn), nickel (Ni), cobalt (Co), lead (Pd), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), silicon carbon nitride (SiCN), or any combination thereof.

The memory cells 170 may be arranged in a matrix form along the first and second directions to overlap with the intersection area of the first wiring 110 and the second wiring 180. In this embodiment, the memory cells 170 have a size less than or equal to the intersection area of the first wiring 110 and the second wiring 180. In other embodiments, the memory cells 170 may have a size greater than this intersection area. The space between the first wiring 110, the second wiring 180, and the memory cell 170 may be embedded with an insulating material.

The memory cell 170 may include a stacked structure, which may include a bottom electrode contact 120, a shift canceling layer 130, a spacer layer 140, a magnetic tunnel junction (MTJ) layer 150, and a selector layer 160. Further, a first interlayer insulating film 125 may be formed to cover sidewalls of the bottom electrode contact 120, and a second interlayer insulating film 165 may be formed to cover sidewalls of the multi-layer (ML) shift canceling layer 130, spacer layer 140, MTJ layer 150, and selector layer 160.

The bottom electrode contact 120 may be formed between the first wiring 110 and the shift canceling layer 130. The bottom electrode contact 120 may be located at the bottom of the memory cell 170, electrically connected to the first wiring 110, and may function as a conduit for transferring current or voltage between the first wiring 110 and the memory cell 170. The bottom electrode contact 120 may include a material capable of forming an insulating layer. For example, the bottom electrode contact 120 may be made of tungsten (W), titanium (Ti), tantalum (Ta), vanadium (V), chromium (Cr), platinum (Pt), aluminum (Al), copper (Cu), zinc (Zn), nickel (Ni), cobalt (Co), lead (Pd), manganese (Mn), niobium (Ni), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or any combination thereof.

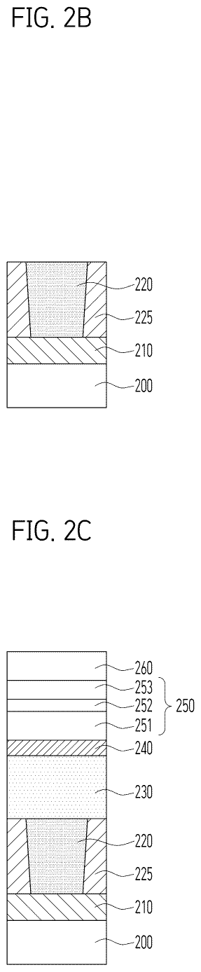

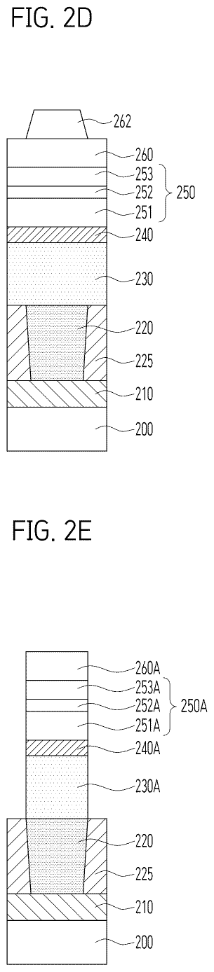

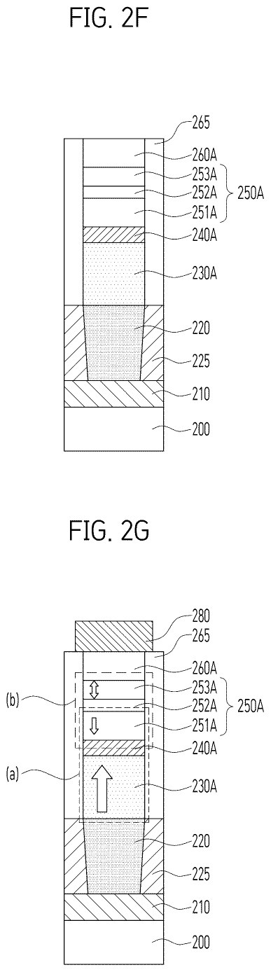

The shift canceling layer 130 may be formed between the bottom electrode contact 120 and the spacer layer 140. The shift canceling layer 130 serves to compensate for magnetic shifts by having a magnetization direction antiparallel to a fixed layer of the MTJ layer 150 (e.g., a fixed layer 251 of FIG. 2C), which can reduce sensitivity to external magnetic field changes, thereby increasing the reliability of the MTJ layer 150 and reducing the occurrence of data errors. By setting the magnetization direction to be antiparallel, it is possible to offset unnecessary magnetization shifts caused by external magnetic fields and increase stability. This reduces magnetic noise in the memory element, enabling the MTJ layer 150 to maintain a constant state and ensuring accurate storage and reading of data. In addition, the shift canceling layer 130 can form a synthetic antiferromagnetic (SAF) structure with the fixed layer to increase magnetic stability and control the magnetic hysteresis of the MTJ layer 150, which can maintain high sensitivity in low magnetic fields. The shift canceling layer 130 can be magnetically coupled to the fixed layer via the spacer layer 140, which is typically composed of a non-magnetic metal such as ruthenium (Ru), Ir, Cr, etc.

One type of a multi-layer (ML) shift canceling layer that has been proposed may have a stacked structure with alternating magnetic (FM) and non-magnetic (NM) layers in a repeating structure. For example, the ML shift canceling layer is a structure such as [FM/NM]n, where each of magnetic and non-magnetic layers can be combined to form the desired magnetic properties. For example, the ML shift canceling layer may have a structure such as [FM/NM]n, where “FM” denotes a ferromagnetic layer, “NM” denotes a non-magnetic layer, and “n” is an integer representing the number of repetitions of the FM/NM bilayer. In this configuration, alternating ferromagnetic and non-magnetic layers are stacked multiple times to form a multilayered structure that provides desired magnetic characteristics. Multilayer shift canceling layers have low thermal stability because interlayer diffusion is likely to occur in high-temperature processes, and the interfacial magnetic anisotropy and synthetic antiferromagnetic properties are degraded. However, the shift canceling layer 130 made from the specific alloy of this embodiment can obtain its magnetic properties directly from the bulk properties of the material itself, and generally has high magnetic anisotropy, making it thermally stable and suitable for high-temperature processes. In addition, the shift canceling layer 130 can be made of a homogeneous alloy and have unique magnetic properties.

The shift cancellation layer 130 may include a Co alloy, Fe alloy, Ni alloy, or Mn alloy comprising at least one selected from the group consisting of aluminum (Al), gallium (Ga), boron (B), iridium (Ir), zirconium (Zr), hafnium (Hf), and rare earth metals, or a ternary or quaternary Co alloy, Fe alloy, Ni alloy, or Mn alloy comprising one of Pt or Pd and at least one selected from the group consisting of Cr, Al, Tb, Si, and B. The shift cancellation layer 130 can provide a SAF structure that maintains its perpendicular magnetic anisotropy (PMA) at high temperatures and does not degrade its synthetic antiferromagnetic (SAF) properties, thereby providing a SAF structure that is resistant to high temperature heat treatment. Overcoming the limitations of one type multilayer shift canceling layers that has been proposed, the inventors have discovered for the first time, a shift canceling layer 130 composed of an alloy that does not degrade its synthetic antiferromagnetic properties at high temperatures.

Specifically, the shift canceling layer 130 may include a Co alloy, Fe alloy, Ni alloy, or Mn alloy comprising at least one selected from the group consisting of aluminum (Al), gallium (Ga), boron (B), iridium (Ir), zirconium (Zr), hafnium (Hf), and rare earth metals. For example, the shift canceling layer 130 may include a Co—Fe—B alloy, a Co—Ir alloy, a Co—Zr—B alloy, a Fe—Ga alloy, a Co—Pt—B alloy, a Co—Tb alloy, or a Ni—Zr—B alloy. Co—Fe—B alloys provide stable vertical magnetic anisotropy (PMA) at high temperatures and can prevent deterioration of SAF properties during high-temperature heat treatment. In particular, the boron (B) can stabilize the grains and contribute to maintaining magnetic performance even after heat treatment. Co—Ir alloy is an ordered phase alloy with a structure of L1₁. Co—Ir alloy has strong PMA properties and can maintain magnetic stability at high temperatures. In particular, iridium (Ir) can enhance corrosion resistance and help maintain stable performance in high temperature and high humidity environments. Co—Zr—B alloys show less degradation at high temperatures and can maintain PMA due to the oxidation resistance of Zr and the grain stabilization effect of boron (B). Co—Zr—B alloys also maintain SAF properties at high temperatures and are suitable for high-density MTJ devices. Fe-Ga alloys have a high magnetostriction coefficient, which allows them to retain their PMA properties even during high-temperature heat treatment. In particular, gallium (Ga) can play a role in increasing the stability of the magnetic domains, which improves the high-temperature performance of MTJ devices. Co—Pt—B alloy is an ordered phase alloy with L1₀ structure. The high temperature stability of Pt and the grain boundary inhibition effect of boron (B) provide excellent PMA, and the SAF properties can be well maintained even after high temperature heat treatment. Pt adds structural stability after heat treatment, which allows for stable long-term performance. Co—Tb alloy is an ordered phase alloy with a D0₁₉ structure and is also a rare earth-transition metal alloy. Co—Tb alloy provides high PMA and thermal stability, resulting in excellent magnetic properties at high temperatures. The inclusion of Tb, rare earth metals, gives it a strong magnetic moment and can help to suppress magnetic degradation. Ni—Zr—B alloys have excellent high-temperature oxidation resistance and can maintain stable magnetic properties even after heat treatment. In particular, the oxidation resistance of Zr combined with the grain inhibition properties of boron can provide high thermal stability. As shift canceling layers (SCLs), these Ni—Zr—B alloys have the advantages of high temperature stability, PMA retention, oxidation resistance, and grain stabilization, which can lead to excellent magnetic properties and long-term performance even after high temperature heat treatment in high-density MTJ devices. The ordered phase alloys have structures such as L1₀, L1₁, and D0₁₉, which provide excellent vertical magnetic anisotropy for the shift canceling layer 130, while the rare earth-transition metal alloys allow the shift canceling layer 130 to have high thermal stability and magnetic properties through the combination of rare earths and transition metals.

The shift canceling layer 130 may comprise a ternary or quaternary Co alloy, Fe alloy, or Ni alloy comprising one of Pt or Pd and at least one selected from the group consisting of Cr, Al, Tb, Si, and B. The shift canceling layer 130 may include, for example, a Co—Pt—Cr alloy, a Fe—Pd—Al alloy, a Co—Ni—Tb alloy, or a Ni—Pd—Si—B alloy.

Co—Pt—Cr alloys maintain stable magnetic properties at high temperatures and provide strong magnetic anisotropy, which can maximize the shift canceling effect. Co—Pt—Cr alloys have a high magnetic moment due to the combination of Co and Pt, and the inclusion of Cr can provide oxidation resistance. Fe—Pd—Al alloys maintain electrical and magnetic stability at the same time, and because Fe—Pd—Al alloy is an Fe-based alloy, Fe—Pd—Al alloy exhibits a high magnetic moment, and Pd and Al can increase its stability. Fe—Pd—Al alloys are resistant to oxidation even at high temperatures, and the Al provides anti-oxidation and lightweighting effects, which can increase the overall thermal stability of the SCL. Co—Ni—Tb alloy is a rare earth-transition metal alloy, in which the rare earth element Tb is added to improve the magnetic properties, and the magnetic stability at high temperature can be maintained. This is because the combination of Co and Ni provides a strong magnetic moment, and the Tb maintains the magnetism, which can ensure the performance of the SAF is stable even at high temperatures. Ni—Pd—Si—B alloy comprises Si and B, which has soft magnetic properties and can have good oxidation resistance. In particular, boron (B) plays a role in stabilizing the magnetic properties to minimize the property change at high temperature, and Pd is added to induce a smooth magnetic transformation. These ternary and tetragonal alloys are characterized by good oxidation resistance and high temperature stability while maintaining high magnetic moments as SCLs. This allows the ternary and tetragonal alloys to maximize the shift cancellation effect in MTJ devices and maintain stable magnetic performance, especially during high-temperature heat treatment.

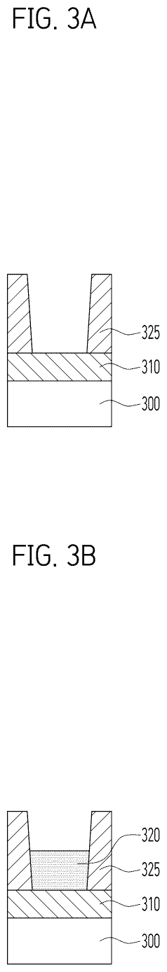

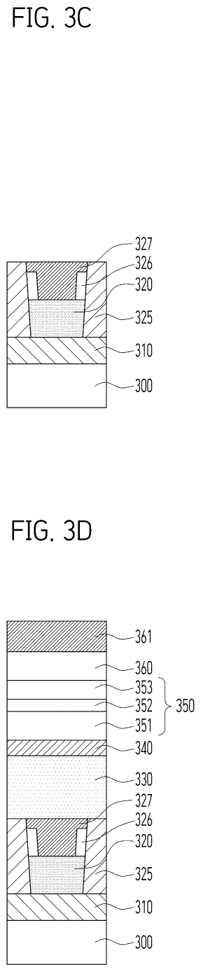

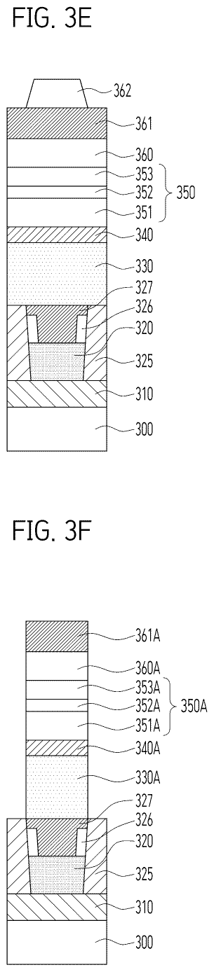

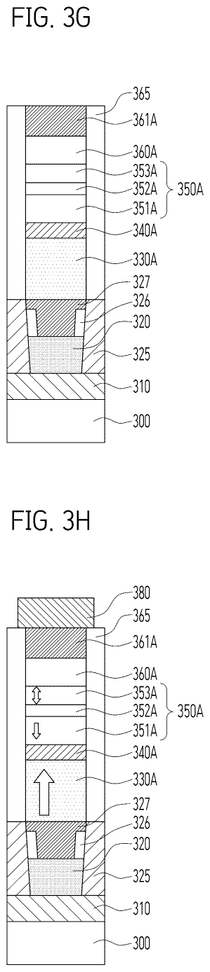

The MTJ layer 150 and the selector layer 160 may be laminated over the spacer layer 140. The MTJ layer 150 includes a fixed layer with a fixed magnetization direction, a free layer with a changeable magnetization direction, and a tunnel barrier layer interposed between the fixed layer and the free layer, which is described in more detail in FIGS. 2G and 3H in accordance with an embodiment of the present disclosure.

The selector layer 160 is implemented as a thin film within the memory cell 170 and may function to control electrical access to one of the plurality of memory cells 170 in an array, while preventing current leakage that may occur between memory cells 170 sharing the first wiring 110 or the second wiring 180. To this end, the selector layer 160 may exhibit threshold switching characteristics, blocking current or allowing minimal current flow when the voltage applied to its top and bottom is below a predetermined threshold voltage, and allowing a rapid flow of current when the voltage exceeds the threshold voltage. The selector layer 160 may turn on when the voltage exceeds the threshold voltage and turn off when the voltage is below the threshold voltage. For example, the selector layer 160 may include an insulating material doped with a dopant.

Each of the first interlayer insulating film 125 and the second interlayer insulating film 165 may include an insulating material, polysilicon (Poly-Si), or a combination thereof, and may be organized in a single-membrane structure or a multi-membrane structure. For example, each of the first interlayer insulating film 125 and the second interlayer insulating film 165 may include silicon oxide, silicon nitride, silicon oxynitride, and/or low-k material. Materials with a dielectric constant (k) of 4 or less are generally referred to as low-k materials, and lower values provide better electrical insulation properties, which reduces parasitic capacitance between devices. These low-k materials include, but are not limited to, silicon oxides, organosiloxanes, silicon carbide, organic-based materials including benzene rings or fluorine, and void materials.

Referring to FIGS. 1B and 1C, the structure may have the bottom electrode contact 120 embedded in all of the recess and the shift canceling layer 130 formed on top of the bottom electrode contact 120, such that the shift canceling layer 130 is not embedded in the recess at all, or the structure may have the bottom electrode contact 120 embedded in a portion of the recess and the shift canceling layer 130 formed on top of it, such that the shift canceling layer 130 is embedded in a portion of the recess.

FIGS. 2A to 2G are cross-sectional views to illustrate a semiconductor device and a method of fabricating the semiconductor device of FIG. 1B, according to an embodiment of the present disclosure. FIGS. 2A to 2G are enlarged cross-sectional views of a single memory cell among the plurality of memory cells in the semiconductor device shown in FIG. 1B. As the parts are substantially the same as the foregoing embodiments, a detailed description will be omitted.

First, the manufacturing method will be described.

Referring to FIGS. 2A and 2B, a first wiring 210 can be formed on a substrate 200 in which a predetermined substructure is formed. The first wiring 210 may be formed by forming an interlayer insulating film having a trench for forming the first wiring 210 on the substrate 200, forming a conductive layer for forming the first wiring 210 in the trench, and etching the conductive layer using a mask pattern in the shape of a line extending in a first direction.

Subsequently, a bottom electrode contact 220 can be formed on the first wiring 210. The bottom electrode contact 220 may be formed by forming a first interlayer insulating film 225 having recesses on the structure formed by the first wiring 210, filling the recesses with a material layer for forming the bottom electrode contact 220, and then performing a planarization process, for example, a chemical mechanical planarization process. The bottom electrode contact 220 may fill all of the recess. If the bottom electrode contact 220 completely fills the recess, the physical stability of the bottom electrode contact 220 is increased, which is advantageous for supporting the superstructure. Further, in this case, the electrical connection area is maximized, contact resistance is likely to be reduced, the planarization process is relatively easy, and surface flatness may be easier to achieve. Specifically, a photolithography and etching process is used to create precisely sized recesses where the bottom electrode contact 220 are to be placed, and the formed recesses are filled with a material layer for the bottom electrode contact 220. The material for the bottom electrode contact 220 may be tungsten (W), titanium (Ti), tantalum (Ta), vanadium (V), chromium (Cr), platinum (Pt), aluminum (Al), copper (Cu), zinc (Zn), nickel (Ni), cobalt (Co), lead (Pd), manganese (Mn), niobium (Ni), or tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or any combination thereof.

Referring to FIG. 2C, a material layer for the formation of a shift canceling layer 230 can be formed on the flattened bottom electrode contact 220 and the first interlayer insulating film 225, and a material layer for the formation of a spacer layer 240 can be formed on top of the shift canceling layer 230. Subsequently, a material layer for forming an MTJ layer 250, including a material layer for forming a fixed layer 251, a material layer for forming a tunnel barrier layer 252, and a material layer for forming a free layer 253, can be formed on top of the material layer for the formation of a spacer layer 240. Subsequently, a material layer for forming the selector layer 260 can be formed. The formation of the material layer for the formation of the fixed layer 251 and the material layer for the formation of the free layer 253 can be deposited by physical vapor deposition (PVD), chemical vapor deposition (CVD), or e-beam deposition. The material layer for the formation of the tunnel barrier layer 252 can be deposited by alkali metal oxide or atom layer deposition (ALD). This method allows for a very thin and uniform oxide film, which allows for precise control of the tunneling current.

Referring to FIG. 2G, the spacer layer 240A may be interposed between the fixed layer 251A and the shift canceling layer 230A to act as a buffer between the fixed layer 251A and the shift canceling layer 230A, enabling antiferromagnetic exchange coupling of the fixed layer 251A and the shift canceling layer 230A, and enhancing the properties of the bottom electrode contact 220. The spacer layer 240A may include a noble metal, such as Ru, Ir, Cr, or a combination thereof. For example, the spacer layer 240A may have a thickness of at least 0.5 nm. As such, having a thickness of at least 0.5 nm of the spacer layer 240A can prevent diffusion or interaction between materials that may occur during a high temperature heat treatment process. These thick spacer layers may act to block deformation or reaction of the materials that may occur at high temperatures, thereby protecting the fixed layer 251A and the shift canceling layer 230A from property changes or degradation. As a result, stability at high temperatures can be maintained. Furthermore, when the thickness of the spacer layer 240A is at least 0.5 nm, the antiferromagnetic exchange bond between the fixed layer 251A and the shift canceling layer 230A may be stronger. This is because the spacer layer 240A can more effectively regulate the interaction between the fixed layer 251A and the shift canceling layer 230A, thereby better controlling the magnetization direction of the fixed layer 251A and increasing the magnetic stability. Further, an intermediate layer may be interposed between the tunnel barrier layer 252A and the fixed layer 251A. The intermediate layer may be the magnetic layer closest to the tunnel barrier layer 252A, and may include Co, Fe, Ni, B, other noble metals, or combinations thereof.

Referring to FIGS. 2D and 2E, a hardmask layer 261 in the form of a pillar can be deposited on the top surface of the material layer for forming the selector layer 260, which can be formed of an insulating material such as silicon nitride or silicon oxynitride. For example, the hardmask layer 261 may comprise at least one of carbon (C), silicon (Si), copper (Cu), tungsten (W), titanium (Ti), tantalum (Ta), aluminum (Al), and nitrides, oxides, borides, and metal nitrides comprising at least one of the foregoing elements (e.g., titanium nitride and tantalum nitride). The hardmask layer 261 in the form of a pillar, serving as an etch barrier, the material layer for forming the shift canceling layer 230, the material layer for forming the spacer layer 240, the material layer for forming the fixed layer 251, and the material layer for forming the tunnel barrier layer 252, the material layer for forming the free layer 253, and the material layer for forming the selector layer 260 can be selectively etched to form a pillar-shaped patterned shift canceling layer 230A, spacer layer 240A, fixed layer 251A, tunnel barrier layer 252A, free layer 253A, and selector layer 260A. The fixed layer 251A, tunnel barrier layer 252A, and free layer 253A may form the MTJ layer 250A.

Referring to FIG. 2F, the second interlayer insulating film 265 can be formed covering the sidewalls of the shift canceling layer 230A, the spacer layer 240A, the selector layer 260A, and the MTJ layer 250A, which includes the fixed layer 251A, the tunnel barrier layer 252A, and the free layer 253A. The second interlayer insulating film 265 can be constructed of a highly insulating material, such as an insulating material, polysilicon (Poly-Si), or a combination thereof, which can provide stability at high temperatures to prevent damage in subsequent processes. The second interlayer insulating film 265 may be deposited to uniformly cover the sidewalls of the MTJ layer 250A and selector layer 260A via chemical vapor deposition (CVD), atomic layer deposition (ALD), or sputtering processes. This allows for electrical isolation of each memory cell along the sidewalls of MTJ layer 250A and selector layer 260A, minimizing surface conductivity and leakage current.

Referring to FIG. 2G, a second wiring 280 can be formed on top of the memory cell. The second wiring 280 may be formed by forming a trench for forming the second wiring 280, depositing a conductive layer for forming the second wiring 280 in the trench, and etching the conductive layer using a line-shaped mask pattern extending in the second direction. The second wiring 280 may be patterned at 90 degrees to the first wiring 210, i.e., the first wiring 210 may be formed to extend in the first direction of FIG. 1A, and the second wiring 280 may be formed to extend in the second direction of FIG. 1A. This formation may result in a semiconductor device having a crosspoint structure in which a memory cell is disposed between the first wiring 210 and the second wiring 280 that intersect each other.

By the above process, a semiconductor device according to an embodiment of the present disclosure can be formed. Referring again to FIG. 2G, a semiconductor device according to this embodiment includes the substrate 200, the first wiring 210, the bottom electrode contact 220, the shift canceling layer 230A, the spacer layer 240A, the MTJ layer 250A including the fixed layer 251A, the tunnel barrier layer 252A, and the free layer 253A, the selector layer 260A, and the second wiring 280. Further, the semiconductor device may include the first interlayer insulating film 225 covering a side wall of the bottom electrode contact 220 and the second interlayer insulating film 265 covering a side wall of the shift canceling layer 230A, the spacer layer 240A, the MTJ layer 250A including the fixed layer 251A, the tunnel barrier layer 252A and the free layer 253A, and the selector layer 260A.

Each of the free layer 253A and the fixed layer 251A may include a material having interfacial vertical magnetic anisotropy. Interfacial vertical magnetic anisotropy refers to a phenomenon in which a magnetic layer having an intrinsic horizontal magnetization characteristic has a vertical magnetization direction due to an influence from an interface with another layer adjacent thereto. Here, the intrinsic horizontal magnetization characteristic means that in the absence of external factors, the magnetic layer has a magnetization direction parallel to its widest surface. For example, when a magnetic layer having an intrinsic horizontal magnetization characteristic is formed on a substrate and there are no external factors, the magnetization direction of the magnetic layer may be substantially parallel to the top surface of the substrate. Each of the free layer 253A and the fixed layer 251A may have a single-membrane structure or a multi-membrane structure comprising a ferromagnetic material. The ferromagnetic material may comprise an alloy based on Fe, Ni, or Co, such as an Fe—Pt alloy, Fe—Pd alloy, Co—Fe alloy, Co—Pd alloy, Co—Pt alloy, Co—Fe—Ni alloy, Fe—Ni—Pt alloy, Co—Fe—Pt alloy, Co—Ni—Pt alloy, Co—Fe—B alloy, or the like, or may comprise a laminated structure, such as Co/Pt, Co/Pd, or the like. The positions of the free layer 253A and the fixed layer 251A may be reversed across the tunnel barrier layer 252A, i.e., the free layer 253A may be positioned above the tunnel barrier layer 252A and the fixed layer 251A may be positioned below the tunnel barrier layer 252A and above the bottom electrode pattern 221. The tunnel barrier layer 252A may enable tunneling of electrons between the free layer 253A and the fixed layer 251A during write operation that changes the resistance state of the variable resistance element, causing the magnetization direction of the free layer 253A to change. The tunnel barrier layer 252A may include at least one of an oxide of magnesium (Mg), an oxide of titanium (Ti), aluminum (Al), an oxide of magnesium-zinc (MgZn), an oxide of magnesium-boron (MgB), a nitride of titanium (Ti), and a nitride of vanadium (V). In one example, the tunnel barrier layer 252A may be a monolayer of magnesium oxide (MgO). Alternatively, the tunnel barrier layer 252A may comprise a plurality of layers. The free layer 253A, the tunnel barrier layer 252A, and the fixed layer 251A may form the MTJ layer 250A, and the variable resistance layer may include such MTJ layer 250A.

The electrical resistance of the MTJ layer 250A may be dependent on the magnetization directions of the fixed layer 251A and the free layer 253A. For example, the electrical resistance of the MTJ layer 250A may be much greater when the magnetization directions of the fixed layer 251A and the free layer 253A are antiparallel than when the fixed layer 251A and the free layer 253A are parallel. As a result, the electrical resistance of the MTJ layer 250A can be adjusted by changing the magnetization direction of the free layer 253A, which can be used as a data storage principle in a semiconductor device according to the present disclosure.

By placing the shift canceling layer 230A at the bottom of the MTJ layer 250A, the semiconductor device of the present embodiment can provide a lower synthetic antiferromagnetic (SAF) structure (i.e., a structure (a) of FIG. 2G), i.e., a structure formed sequentially by the shift canceling layer 230A, the spacer layer 240A, and the fixed layer 251A, to provide a strong vertical magnetic anisotropy (PMA), thereby increasing the exchange bias field (Hex). By placing the SAF structure at the bottom in this embodiment, the stability against external magnetic fields can be increased and the reliability of data storage can be improved.

Furthermore, the semiconductor device of this embodiment replaces the multilayer shift canceling layer (SCL layer) that has been proposed with the shift canceling layer 230A that includes either a Co alloy, Fe alloy, Ni alloy, or Mn alloy comprising at least one selected from the group consisting of Al, Ga, B, Ir, Zr, Hf, and rare-earth metals; or a ternary or quaternary Co alloy, Fe alloy, or Ni alloy comprising one of Pt or Pd and at least one selected from the group consisting of Cr, Al, Tb, Si, and B. This replacement enables high temperature heat treatment of the MTJ layer 250A, thereby promoting crystallization and significantly enhancing the magnetoresistance (MR). The multilayer SCL structure that has been proposed had a concern in which inter-diffusion occurred within the SCL layer during high temperature heat treatment, leading to the degradation of synthetic antiferromagnetic properties. However, in this embodiment, the multilayer SCL structure is replaced with a specific alloy, e.g., an ordered phase alloy having bulk magnetic anisotropy, a rare earth-transition metal (RE-TM) alloy, or a ternary or quaternary Co, Fe, or Ni alloy comprising certain elements to enhance the thermal stability of the SAF. The shift canceling layer 230A fabricated with such a specific alloy exhibits superior magnetic properties compared to a [FM/NM]*n structure that has been proposed, which can increase the magnetoresistance (MR) of a structure in which the fixed layer 251A, the tunnel barrier layer 252A, and the free layer 253A are arranged sequentially (i.e., a structure (b) of FIG. 2G). As a result, the read/write efficiency of the semiconductor device can be greatly improved. Thus, the shift canceling layer 230A of the present embodiment enables the realization of a high-performance spintronics device through a combination that can simultaneously achieve an increase in the exchange bias field (Hex) and an increase in the magnetoresistance (MR), and provides a solution to overcome the limitation of high-temperature heat treatment that occurs in conventional technologies.

The process structure of FIG. 2G may be substantially the same as the process structure of FIG. 1B described above. That is, the substrate 200, the first wiring 210, the bottom electrode contact 220, the first interlayer insulating film 225, the shift canceling layer 230A, the spacer layer 240A, the MTJ layer 250A, the selector layer 260A, the second interlayer insulating film 265, and the second wiring 280 corresponds to the substrate 100, the first wiring 110, the bottom electrode contact 120, the first interlayer insulating film 125, the shift canceling layer 130, the spacer layer 140, the MTJ layer 150, the selector layer 160, the second interlayer insulating film 165, and the second wiring 180 of FIG. 1B, respectively. Therefore, a detailed description of the process structure and corresponding parts of FIG. 1B above will be omitted.

FIGS. 3A to 3H are cross-sectional views to illustrate a semiconductor device and a method of fabricating the semiconductor device of FIG. 1C, according to another embodiment of the present disclosure. FIGS. 3A to 3H are enlarged cross-sectional views illustrating a single memory cell among the plurality of memory cells in the semiconductor device shown in FIG. 1C. As the parts are substantially the same as the foregoing embodiments, a detailed description will be omitted.

First, the manufacturing method will be described.

Referring to FIGS. 3A and 3B, a first wiring 310 may be formed on a substrate 300 in which a predetermined substructure is formed.

Subsequently, a bottom electrode contact 320 can be formed on the first wiring 310. The bottom electrode contact 320 may be formed by forming a first interlayer insulating film 325 having a recess on the structure formed by the first wiring 310, filling the recess with a material layer for forming the bottom electrode contact 320, and then performing a planarization process, such as a chemical or mechanical planarization process. The bottom electrode contact 320 may fill only a portion of the recess. If the bottom electrode contact 320 fills only a portion of the recess, the amount of filling material used may be reduced, which may result in shorter process times and lower costs. This formation is also advantageous for reducing internal stresses that may occur. This formation can be useful when the thicker the film, the greater the potential for stress-induced cracking or deformation. In particular, designing the bottom electrode contact 320 so that the bottom electrode contact 320 fills only a portion of the recess and the shift canceling layer is partially embedded can also create conditions that allow the canceling layer to play a more effective role.

Referring to FIG. 3C, a material layer may first be deposited to form a spacer 326, which covers the inner walls of the recess and the surface of the first interlayer insulating film 325. The spacer 326 may be formed by partially removing the material layer for forming the spacer 326. The process for forming the spacer 326 may include an anisotropic etch process, an isotropic etch process, or a combination thereof.

The spacer 326 may include a material having an etch selectivity relative to the first interlayer insulating film 325. The spacer 326 may include a dielectric material such as silicon oxide, silicon nitride, silicon oxynitride, or a combination thereof. For example, the spacer 326 may include a material with poor stepcoverage and low electrical conductivity. For example, the spacer 326 may include a material having carbon groups. The spacer 326 may include amorphous carbon, and may include oxides such as undoped silica glass (USG). The spacer 326 may be formed on a sidewall of the recess. A lower surface of the spacer 326 may contact the bottom electrode contact 320. The top surface of the spacer 326 may be formed at a level lower than the top surface of the first interlayer insulating film 325. A sidewall of the recess may be exposed at the top of the spacer 326. The bottom of the recess may expose the first interlayer insulating film 325.

Subsequently, a first electrode layer 327 may be formed in the recess. The formation of the first electrode layer 327 can be subject to a thin film formation process and an etch-back process. The first electrode layer 327 may include a conductive material such as a metal, metal nitride, metal oxide, metal silicide, conductive carbon, or a combination thereof. For example, the first electrode layer 327 may include TiN. The first electrode layer 327 may contact the bottom electrode contact 320. The top of the first electrode layer 327 may be formed at a level higher than the top of the spacer 326. The sides of the first electrode layer 327 may be surrounded by the spacer 326. The first electrode layer 327 may be confined by the spacer 326. The top of the first electrode layer 327 may have a variety of shapes, such as a recessed shape at a lower level toward the center or a protruded shape at a higher level toward the center. However, for simplicity, it will be described as having a flat shape.

Referring to FIG. 3D, a material layer for the formation of a shift canceling layer 330 can be formed on the planarized first electrode layer 327 and the first interlayer insulating film 325, and a material layer for the formation of a spacer layer 340 can be formed on the shift canceling layer 330. Subsequently, a material layer for forming an MTJ layer 350, including a material layer for forming a fixed layer 351, a material layer for forming a tunnel barrier layer 352, and a material layer for forming a free layer 353, can be formed on top of the spacer layer 340 in turn. Subsequently, a material layer for forming a selector layer 360 can be formed, and a material layer for forming a second electrode layer 361 can be formed.

Referring to FIGS. 3E and 3F, a pillar-shaped hardmask layer 362 is deposited on the upper surface of a material layer for forming a second electrode layer 361. The pillar-shaped hardmask layer 362 is used as an etch barrier to selectively etch the material layer for forming the shift canceling layer 330, the material layer for forming the spacer layer 340, the material layer for forming the fixed layer 351, and the material layer for forming the tunnel barrier layer 352, material layer for forming the free layer 353, the material layer for forming the selector layer 360, and the material layer for forming the second electrode layer 361 can be selectively etched to form a pillar-shaped patterned shift canceling layer 330A, spacer layer 340A, fixed layer 351A, tunnel barrier layer 352A, free layer 353A, selector layer 360A, and second electrode layer 361A. The fixed layer 351A, the tunnel barrier layer 352A, and the free layer 353A may form the MTJ layer 350A. A variable resistance layer may include such MTJ layer 350A.

Referring to FIGS. 3G and 3H, the second interlayer insulating film 365 can be formed covering the sidewalls of the shift canceling layer 330A, the spacer layer 340A, the selector layer 360A, the second electrode layer 361A, and the MTJ layer 350A including the fixed layer 351A, the tunnel barrier layer 352A, and the free layer 353A. Subsequently, a second wiring 380 can be formed on top of the memory cell. For example, the second electrode layer 361A may comprise at least one of a conductive metal nitride (e.g., titanium nitride or tantalum nitride) and rare earth metals (e.g., lucenium, platinum, etc.).

By the above process, a semiconductor device according to an embodiment of the present disclosure can be formed. Referring again to FIG. 3H, a semiconductor device according to an embodiment of the present disclosure may be formed with the substrate 300, first wiring 310, bottom electrode contact 320, spacer 326, first electrode layer 327, shift canceling layer 330A, spacer layer 340A, selector layer 360A, second electrode layer 361A, second wiring 380, and the MTJ layer 350A, including the fixed layer 351A, tunnel barrier layer 352A, and free layer 353A. The semiconductor device further includes the first interlayer insulating film 325, which covers the sidewalls of the bottom electrode contact 320, and the second interlayer insulating film 365, which covers the sidewalls of the shift canceling layer 330A, spacer layer 340A, selector layer 360A, second electrode layer 361A, and MTJ layer 350A, including the fixed layer 351A, tunnel barrier layer 352A, and free layer 353A. In this embodiment, all advantages described in the preceding embodiments may be obtained.

By placing the shift canceling layer 330A at the bottom of the MTJ layer 350A, the semiconductor device of the present embodiment can provide a lower synthetic antiferromagnetic (SAF) structure (i.e., a structure (a) of FIG. 3H), i.e., a structure formed sequentially by the shift canceling layer 330A, the spacer layer 340A, and the fixed layer 351A, to provide a strong vertical magnetic anisotropy (PMA), thereby increasing the exchange bias field (Hex). By placing the SAF structure at the bottom in this embodiment, the stability against external magnetic fields can be increased and the reliability of data storage can be improved.

Furthermore, the semiconductor device of the present embodiment replaces the conventional multilayer shift canceling layer (SCL layer) with the shift canceling layer 330A comprising either a ternary or quaternary Co alloy, Fe alloy, Ni alloy, or Mn alloy comprising at least one selected from the group consisting of Al, Ga, B, Ir, Zr, Hf, and rare earth metals, or one of Pt or Pd and Cr, Al, Tb, Si, and B. This substitution enables high-temperature heat treatment of the MTJ layer 350A, which promotes crystallization and dramatically increases the magnetoresistance (MR). In multilayer SCL structures that have been proposed, interdiffusion within the SCL layer during high-temperature heat treatment caused degradation of synthetic antiferromagnetic (SAF) properties. However, in this embodiment, the multilayer SCL structure can be replaced with a specific alloy, e.g., an ordered phase alloy with bulk magnetic anisotropy, a rare earth-transition metal (RE-TM) alloy, or a ternary or quaternary Co alloy, Fe alloy, or Ni alloy comprising certain elements to enhance the thermal stability of the SAF. The shift canceling layer 330A fabricated with such specific alloys exhibits superior magnetic properties compared to a [FM/NM]*n structure that has been proposed, which can increase the magnetoresistance (MR) of a structure in which the fixed layer 351A, the tunnel barrier layer 352A, and the free layer 353A are arranged sequentially (i.e., a structure (b) of FIG. 3H). As a result, the read/write efficiency of the semiconductor device can be greatly improved. Thus, the shift canceling layer 330A of the present embodiment realizes a high-performance spintronics device through a combination that can simultaneously achieve an increase in the exchange bias field (Hex) and an increase in the magnetoresistance (MR), and provides a solution to overcome the limitation of high-temperature heat treatment that occurs in conventional technologies.

The process structure of FIG. 3H may be substantially the same as the process structure of FIG. 1C described above. That is, the substrate 300, the first wiring 310, the bottom electrode contact 320, the first interlayer insulating film 325, the shift canceling layer 330A, the spacer layer 340A, the MTJ layer 350A, the selector layer 360A, the second interlayer insulating film 365, and the second wiring 380 may correspond to the substrate 100, the first wiring 110, the bottom electrode contact 120, the first interlayer insulating film 125, the shift canceling layer 130, the spacer layer 140, the MTJ layer 150, the selector layer 160, the second interlayer insulating film 165, and the second wiring 180 of FIG. 1C, respectively. Therefore, a detailed description of the process structure of FIG. 1C and the corresponding parts will be omitted.

According to the semiconductor device described above and the manufacturing method thereof, by disposing a shift canceling layer on the lower part of the MTJ layer, a lower SAF structure is formed. At the same time, the multilayer SCL structure with a [FM/NM]*n configuration can be replaced with a shift canceling layer formed from a specific alloy, such as an ordered phase alloy having a bulk magnetic anisotropy, a rare earth-transition metal (RE-TM) alloy, or a ternary or quaternary Co alloy, Fe alloy, or Ni alloy comprising a specific element. As a result, the semiconductor device of this embodiment may provide strong vertical magnetic anisotropy (PMA), which may increase the exchange bias field (Hex) while simultaneously increasing the magnetoresistance (MR) of the MTJ layer. Thereby, the read/write efficiency of the semiconductor device can be significantly improved.

According to the above-described embodiments of the present disclosure, a semiconductor device and a method of manufacturing the same can provide stable exchange coupling even at high temperatures while achieving high exchange bias field (Hex) and magnetoresistance (MR) by forming a shift canceling layer (SCL) using a specific alloy to prevent SAF property deterioration that may occur during high-temperature heat treatment.

While the embodiments of the present disclosure have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device, comprising:
a substrate;
an interlayer insulating film disposed on the substrate and having a recess exposing a portion of the substrate;
a bottom electrode contact (BEC) that embeds at least a portion of the recess;
a magnetic tunnel junction (MTJ) layer comprising a fixed layer disposed on the interlayer insulating film and the bottom electrode contact, and having a fixed magnetization direction, a free layer having a changeable magnetization direction, and a tunnel barrier layer interposed between the free layer and the fixed layer; and
a shift canceling layer having a magnetization direction antiparallel to the fixed layer,
wherein the shift canceling layer comprises a magnetic alloy selected from the group consisting of:
(i) a cobalt (Co)-based alloy or an iron (Fe)-based alloy comprising at least one element selected from the group consisting of aluminum (Al), gallium (Ga), boron (B), iridium (Ir), zirconium (Zr), hafnium (Hf), and rare earth metals;
(ii) nickel (Ni)-based alloy or manganese (Mn)-based alloy comprising at least one element selected from the group consisting of aluminum (Al), gallium (Ga), boron (B), iridium (Ir), zirconium (Zr), hafnium (Hf), and rare earth metals; and
(iii) a ternary or quaternary alloy comprising Co, Fe, or Ni, and further comprising one of platinum (Pt) or lead (Pd), and at least one element selected from the group consisting of chromium (Cr), aluminum (Al), terbium (Tb), silicon (Si), and boron (B).

2. The semiconductor device of claim 1, wherein the shift canceling layer is interposed between the bottom electrode contact and the MTJ layer.

3. The semiconductor device of claim 1, wherein the shift canceling layer comprises the cobalt (Co)-based alloy.

4. The semiconductor device of claim 1, wherein the shift canceling layer comprises the cobalt (Co)-based alloy or the iron (Fe)-based alloy comprising rare earth metals.

5. The semiconductor device of claim 1, wherein the shift canceling layer comprises the nickel (Ni)-based alloy or the manganese (Mn)-based alloy.

6. The semiconductor device of claim 1, further comprising a spacer layer interposed between the fixed layer and the shift canceling layer,
wherein the fixed layer and the shift canceling layer are antiferromagnetically exchange-coupled through the spacer layer to form a synthetic antiferromagnetic (SAF) structure.

7. The semiconductor device of claim 6, wherein the spacer layer comprises ruthenium (Ru), Ir, Cr, or a combination thereof.

8. The semiconductor device of claim 6, wherein the spacer layer has a thickness of at least 0.5 nm.

9. The semiconductor device of claim 1, further comprising an intermediate layer interposed between the fixed layer and the tunnel barrier layer.

10. The semiconductor device of claim 9, wherein the intermediate layer comprises Co, Fe, Ni, B, a noble metal, or a combination thereof.

11. The semiconductor device of claim 1, further comprising:
an electrode layer disposed over the bottom electrode contact and embedding an upper portion of the recess, and
a spacer formed on a side of the electrode layer.

12. A method for fabricating a semiconductor device, the method comprising:
forming an interlayer insulating film on a substrate;
selectively etching the interlayer insulating film to form a recess exposing a portion of the substrate;
forming a bottom electrode contact that embeds at least a portion of the recess; and
forming a shift canceling layer and a variable resistance element on the bottom electrode contact,
wherein the shift canceling layer comprises a magnetic alloy selected from the group consisting of:
(i) a cobalt (Co)-based alloy or an iron (Fe)-based alloy comprising at least one element selected from the group consisting of aluminum (Al), gallium (Ga), boron (B), iridium (Ir), zirconium (Zr), hafnium (Hf), and rare earth metals;
(ii) nickel (Ni)-based alloy or manganese (Mn)-based alloy comprising at least one element selected from the group consisting of aluminum (Al), gallium (Ga), boron (B), iridium (Ir), zirconium (Zr), hafnium (Hf), and rare earth metals; and
(iii) a ternary or quaternary alloy comprising Co, Fe, or Ni, and further comprising one of platinum (Pt) or lead (Pd), and at least one element selected from the group consisting of chromium (Cr), aluminum (Al), terbium (Tb), silicon (Si), and boron (B).

13. The method of claim 12, wherein the forming the variable resistance element comprises:
forming a magnetic tunnel junction (MTJ) layer comprising a fixed layer having a fixed magnetization direction, a tunnel barrier layer, and a free layer having a changeable magnetization direction, which are stacked sequentially on the shift canceling layer.

14. The method of claim 13, wherein the shift canceling layer has a magnetization direction antiparallel to the fixed layer.

15. The method of claim 13, wherein the shift canceling layer comprises the cobalt (Co)-based alloy.

16. The method of claim 12, wherein the shift canceling layer comprises the cobalt (Co)-based alloy or the iron (Fe)-based alloy comprising rare earth metals.

17. The method of claim 12, wherein the shift canceling layer comprises the nickel (Ni)-based alloy or the manganese (Mn)-based alloy.

18. The method of claim 13, further comprising forming a spacer layer on the shift canceling layer before forming the MTJ layer,
wherein the fixed layer and the shift canceling layer are antiferromagnetically exchange-coupled through the spacer layer to form a synthetic antiferromagnetic (SAF) structure.

19. The method of claim 18, wherein the spacer layer comprises ruthenium (Ru), Ir, Cr, or a combination thereof.

20. The method of claim 18, wherein the spacer layer has a thickness of at least 0.5 nm.

21. The method of claim 13, further comprising forming an intermediate layer between the fixed layer and the tunnel barrier layer.

22. The method of claim 21, wherein the intermediate layer comprises Co, Fe, Ni, B, a noble metal, or a combination thereof.

23. The method of claim 12, further comprising forming an electrode layer in an upper portion of the recess over the bottom electrode contact.
